(19) United States
(12) Patent Application Publication
(10) Pub. No.: US 2026/0221888 A1
(43) Pub. Date: Jul. 30, 2026

(54) DIRECT CURRENT BALANCING USING A ZERO VOLTAGE DETECTION SIGNAL

(71) Applicant: Texas Instruments Incorporated, Dallas, TX (US)

(72) Inventor: Vsevolod Igorevich Elantsev, Freising (DE)

(21) Appl. No.: 19/085,454

(22) Filed: Mar. 20, 2025

Related U.S. Application Data
(60) Provisional application No. 63/749,954, filed on Jan. 27, 2025.

(51) Int. Cl. H02M 3/335; H02M 1/00; H02M 1/08; H02M 1/38

(52) U.S. Cl. CPC H02M 3/33576; H02M 1/0058; H02M 1/08; H02M 1/38; H02M 3/33573

(57) ABSTRACT

Methods, apparatus, systems, and articles of manufacture are described for direct current balancing using a zero voltage detection signal. An example system includes a transformer circuit; a transistor coupled to the transformer circuit; zero voltage detection circuitry coupled to the transistor; and a controller coupled to the transistor, coupled to the zero voltage detection circuitry, and configurable to: receive a signal from the zero voltage detection circuitry; detect that one or more pulses are missing from the signal received from the zero voltage detection circuitry; and control the transistor in response to detecting that the one or more pulses are missing from the signal.

### CROSS REFERENCE TO RELATED APPLICATION

This patent application claims the benefit of and priority to U.S. Provisional Patent Application No. 63/749,954 , filed Jan. 27, 2025, which Application is hereby incorporated herein by reference in its entirety.

### TECHNICAL FIELD

This description relates generally to circuits, and, more particularly, to direct current balancing using a zero voltage detection signal.

### BACKGROUND

Many devices have circuitry to charge batteries of the devices using an external voltage supply. For example, a computer has a connection that may be connected through circuitry to a wall outlet. When plugged in, the power supply coming from the wall outlet can be used to charge the computer battery. Also, in electric or plug in hybrid vehicles, a connector can be attached to the vehicle(s) to charge the vehicle battery using an electrical output of supercharger.

To charge the battery of the device without causing damage, a power converter can convert the power source from a first voltage to a second voltage that is safe for charging the battery. The power source may be an alternating current (AC) voltage source (e.g., that is converted to a direct current (DC) voltage source through an AC-to-DC converter) or a DC voltage source. Such devices typically include a dual active bridge DC-DC converter or full bridge transformer topology to convert the incoming DC voltage to the DC voltage that is safe for charging the battery. Dual active bridge DC-DC converters or full bridge transformer topologies utilize a plurality of transistors and a transformer to convert the input DC voltage to an AC signal based on a bridge topology and convert the AC signal back to a different DC voltage using a rectifier topology.

### SUMMARY

For a direct current balancing using a zero voltage detection signal, an example system includes a transformer circuit; a transistor coupled to the transformer circuit; zero voltage detection circuitry coupled to the transistor; and a controller coupled to the transistor, coupled to the zero voltage detection circuitry, and configurable to: receive a signal from the zero voltage detection circuitry; detect that one or more pulses are missing from the signal received from the zero voltage detection circuitry; and control the transistor in response to detecting that the one or more pulses are missing from the signal. Other examples are described.

For a direct current balancing using a zero voltage detection signal, an example system includes a transformer circuit; a first transistor coupled to the transformer circuit; first zero voltage detection circuitry coupled to the first transistor; a second transistor coupled to the transformer circuit; second zero voltage detection circuitry coupled to the second transistor; and a controller coupled to the first transistor, the first zero voltage detection circuitry, the second transistor, and the second zero voltage detection circuitry, wherein the controller is operable to control the first transistor and the second transistor based on a mismatch between a first signal received from the first zero voltage detection circuitry and a second signal received from the second zero voltage detection circuitry. Other examples are described.

For a direct current balancing using a zero voltage detection signal, an example system includes a transformer; a first transistor coupled to the transformer; a second transistor coupled to the transformer; first zero voltage detection circuitry operable to output a pulse based on a drain to source voltage of the first transistor being negative when the first transistor turns on; second zero voltage detection circuitry operable to output a pulse based on a drain-to-source voltage of the second transistor being negative when the second transistor turns on; and a controller coupled to the first zero voltage detection circuitry and the second zero voltage detection circuitry, wherein the controller is operable to mitigate direct current content in an alternative current applied to the transformer based on at least one of a first count of pulses from the first zero voltage detection circuitry or a second count of pulses from the second zero voltage detection circuitry. Other examples are described.

### BRIEF DESCRIPTION OF THE DRAWINGS

FIG. 1 is a diagram of various types of contactors in an EV or HEV environment.

FIG. 2 is an example system for charging a battery.

FIG. 3 illustrates example circuity to implement a portion of the system of FIG. 3.

FIG. 4 illustrates an example implementation of the transistor circuitry of FIGS. 2 and 3.

FIG. 5 is a block diagram of an example implementation of the controller of FIG. 3.

FIG. 6 is a timing diagram described in conjunction with the system of FIGS. 2 and 3.

FIGS. 7-9 are flowcharts representative of a method, instructions, and/or operations that may be executed to implement the computing device of FIGS. 3 and 5.

FIG. 10 is a block diagram of an example processing platform including programmable circuitry structured to execute, instantiate, and/or perform the example machine readable instructions and/or perform the example operations of FIGS. 7-9 to implement the controller of FIG. 5.

The same reference numbers or other reference designators are used in the drawings to designate the same or similar (functionally and/or structurally) features.

The drawings are not necessarily to scale. Generally, the same reference numbers in the drawing(s) and this description refer to the same or like parts. Although the drawings show regions with clean lines and boundaries, some or all of these lines and/or boundaries may be idealized. In reality, the boundaries and/or lines may be unobservable, blended and/or irregular.

### DETAILED DESCRIPTION

Transformer systems, such as dual active bridge DC-DC converters and/or full bridge transformer topologies, are used to charge batteries and/or store charge in a plurality of systems. For example, transformer systems may be implemented in solar microinverters, energy storage systems, power grids, power converters for solar panels, battery management systems, solar panels, wind turbines, other power generation systems (e.g., hydrocarbon, hydroelectric, nuclear, etc.), DC chargers for computing devices, DC chargers for electric and/or hybrid vehicles, DC chargers in other systems, power supplies, phone chargers, laptop chargers, etc.

Some transformer systems utilize a transformer coupled to a first circuit that includes a power supply and a plurality of switches (e.g., in a bridge or full bridge structure) and a second circuitry that includes a battery or power storage unit and a second plurality of switches (e.g., in a rectifier structure). Such transformer systems can convert the DC voltage of the power supply to an AC signal using the transformer and the first circuit and convert the AC signal to a different DC voltage to charge the battery or power storage unit. Such full bridge transformer topologies generate an AC current in the winding of the transformer. However, non-idealities and/or mismatch between switches on the first side of the system can create DC content in the AC signal. The DC content can cause the AC signal (e.g., the root-mean square (RMS) current associated with the AC signal) to increase over time. If the AC signal increases too high, the AC signal can saturate the core of the transformer, causing an increase in conduction losses, increased switching losses, and/or AC current to increase to dangerous levels that could damage the system.

To avoid and/or mitigate DC content in the AC current through a transformer, some transformer topologies include a capacitor to block the DC content. Although adding a capacitor can mitigate DC content in some transformer systems, the capacitor needs to be sufficiently large and have very low equivalent series resistance (ESR) (e.g., to reduce power loss) to properly mitigate DC content in high switching environments. Thus, the use of capacitors adds significant printed circuit board (PCB) area and cost (e.g., the cost to purchase and install the capacitor) to transformer topologies. Also, even with low ESR, a capacitor-based technique results in some power loss. Another technique to avoid and/or mitigate DC content in the AC current through a transfer is to implement a current sensor. For example, a controller can monitor the current through the transformer via the current sensor and determine if the current is increasing or decreasing over multiple periods of the current signal, which corresponds to DC content in the AC current. After DC content has been determined, the controller can perform one or more DC content mitigation techniques to reduce the DC content in the AC current. However, like the capacitor approach, the use of a current sensor also results in a significant increase in PCB area, cost (e.g., the cost to purchase and install the sensor), and/or power loss.

Examples disclosed herein include a DC content mitigation technique that leverages circuitry already included in transistor chips. Thus, examples disclosed herein can mitigate DC content without adding components such as current sensors and DC blocking capacitors, which results in no minimal power loss and no additional cost or PCM area to implement. Examples disclosed herein increase efficiency by protecting switches from the effects of transformer core saturation with less expense and a smaller form factor than using DC blocking capacitors or current sensing. The examples disclosed herein can also make soft switching easier to achieve, even when the input voltage or load changes.

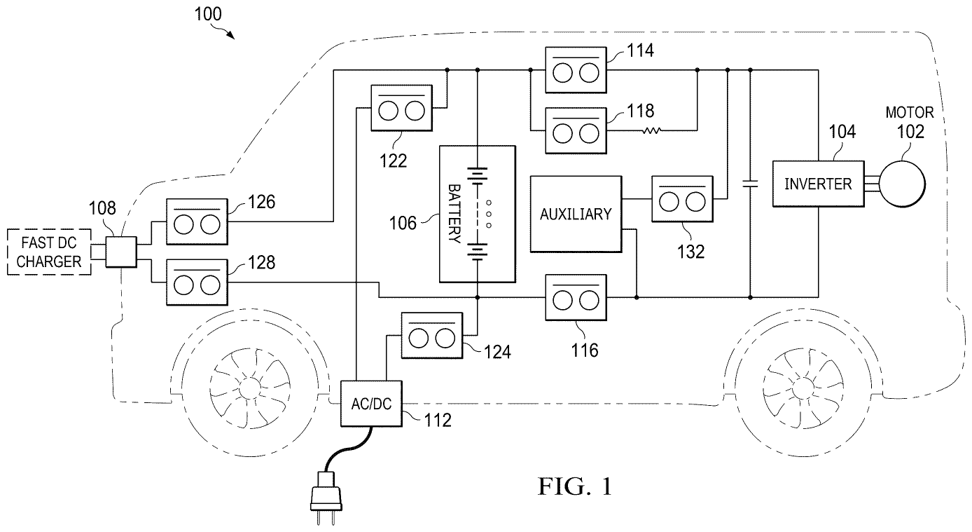

FIG. 1 is a schematic diagram of a vehicle 100, which is an electric vehicle (EV) or hybrid electric vehicle (HEV), showing various types of contactors that may be used in such a vehicle. The illustration may be over inclusive in that not all of the contactors shown are necessarily used in either an EV or an HEV. The illustration is intended to give non-exhaustive examples of various contactors.

Vehicle 100 includes a motor 102 and traction inverter 104 coupled to motor 102. Vehicle 100 also includes a battery 106 and a fast DC charge port 108 that is adapted to receive DC charge from an external source. An HEV also includes an AC/DC onboard charger 112.

In the illustrated example, two main contactors 114 and 116 electrically isolate battery 106 and traction inverter 104 when vehicle 100 is switched off for safety. Main contactor 114 is a positive contactor that is disposed between the positive terminal of battery 106 and traction inverter 104. Main contactor 116 is a negative contactor that is disposed between the negative terminal of battery 106 and traction inverter 104. A pre-charge contactor 118 with series-coupled current-limiting resistance is coupled in parallel with main positive contactor 114. Pre-charge contactor 118 is used to charge an initially discharged DC link capacitor before closing main contactors 114 and 116 to avoid a high inrush-current that may damage the battery 106, one or both of main contactors 114 and 116, and/or the DC link capacitor.

When vehicle 100 is an HEV with plug-in charge capability, a pair of additional AC charge contactors 122 and 124 are included to establish connection between battery 106 and AC/DC onboard charger 112, which includes a plug to access an AC electrical source (e.g., an AC electrical outlet), converts that AC electricity to DC electricity to charge the battery 106.

When vehicle 100 is an EV, a pair of DC fast charge contactors 126 and 128 to establish connection between fast DC charge port 108 and battery 106. An auxiliary contactor 132 is included for auxiliary components, e.g., the electric heating/cooling system.

Main contactors 114 and 116, pre-charge contactor 118, and DC charge contactors 126 and 128 are usually located in the battery junction box (or battery disconnect unit), while AC charger contactors 122 and 124 are likely to be placed in the battery power distribution unit, which is typically adjacent to AC/DC onboard charger 112.

When the controller for any of the above-identified contactors is turned-off, current in the load is discharged through a current decay path and as a result power is dissipated to effectuate quick-turn-off (QTO). High-side (HS) and low-side (LS) clamps are used in conjunction with drivers and a control circuit to carry out QTO.

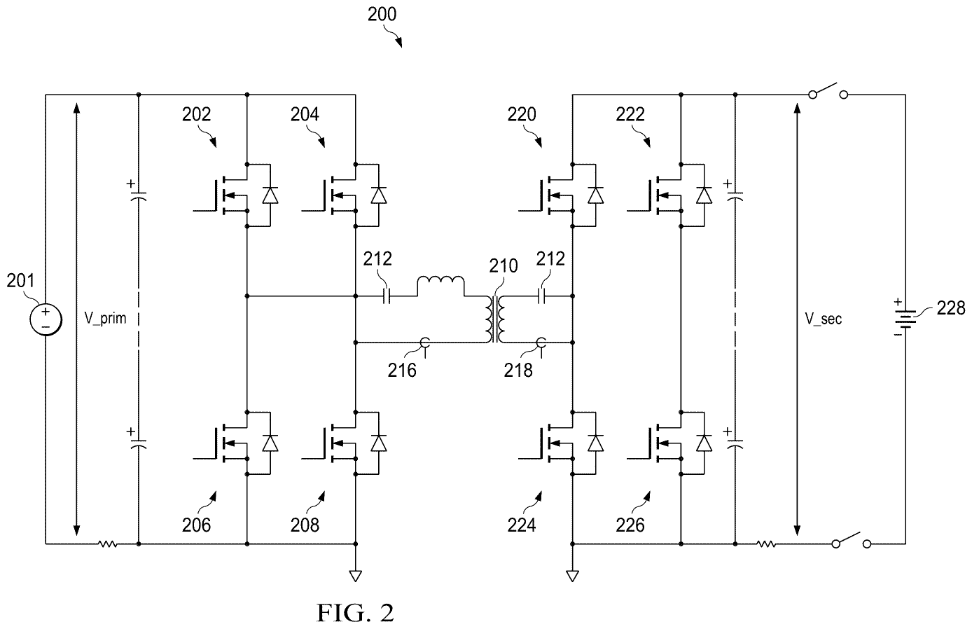

FIG. 2 is an example system 200 for charging a battery (e.g., the battery 106 of FIG. 1). The system 200 can be implemented in the DC charge port 108 and/or the AC/DC onboard charger 112 of FIG. 1. Alternatively, the system 200 could be implemented in solar microinverters, energy storage systems, power grids, battery management systems, solar panels, DC chargers for computing devices, DC chargers for electric and/or hybrid vehicles, DC chargers in other systems, power supplies, etc. The system 200 includes an example supply voltage and/or power source 201, example transistor circuitry 202, 204, 206, 208, 220, 222, 224, 226, an example transformer 210, example DC blocking capacitors 212, 214, example current sensors 216, 218, and an example battery 228. In some examples, the battery 228 corresponds to the battery 106 of FIG. 1. The system 200 implements a full bridge transformer system for converting a first DC voltage to a second DC voltage. However, a system implementing the techniques of this disclosure may have a different converter structure. Although the example of FIG. 2 illustrates a full bridge structure for the transistor circuitries 202, 204, 206, 208, examples disclosed herein can be used in conjunction with a half bridge structure (e.g., including two transistors, for example) or any other power converter topology.

The power source 201 of FIG. 1 provides a first voltage that is converted through the transformer 210 and based on control of the transistor circuitries 202, 204, 206, 208 to a second voltage through the transformer 210 and rectification based on the transistor circuitries 220, 222, 224, 226. The second voltage charges the battery 228. As further described below, a controller outputs control signals to the transistor circuitry 202, 204, 206, 208 to toggle between applying positive supply of the power source 201 to the transformer 210 and applying the negative supply of the power source 201 to the transformer 210. For example, the controller can apply pulse-width modulated (PWM) signals to the transistor circuitries 202, 204, 206, 208 (e.g., by adjusting the on time of the transistors) to cause the transistor circuitries 202, 208 to turn on/conduct (e.g., operate at a short circuit) while the transistor circuitries 204, 206 are off (e.g., operate as an open circuit) for a duration of time to apply the positive terminal of the power source 201 to the transformer 210 followed by causing the transistor circuitries 202, 208 to turn off (e.g., operate at an open circuit) while the transistor circuitries 204, 206 are on/conducting (e.g., operate as a closed circuit) for a duration of time to apply the negative terminal of the power source 201. In some examples, the control signal applied to the transistor circuitry 202 and the control signal to the transistor 204 are opposites and the control signal applied to the transistor circuitry 206 and the control signal applied to the transistor circuitry 208 are opposites (e.g., when the first control signal is high, the second control signal is low), where the control signal applied to the transistor circuitry 202 and the control signal applied to the transistor circuitry 208 are phase shifted. This procedure repeats from period to period. Based on the control of the transistors 220, 222, 224, 226 the voltage across the terminals of the transistor will vary between the positive supply voltage and the opposite of the supply voltage. The transistors 220, 222, 224, 226 rectify the output voltage to convert the voltage of the power source 201 from a first voltage to a second voltage used to charge the battery 228.

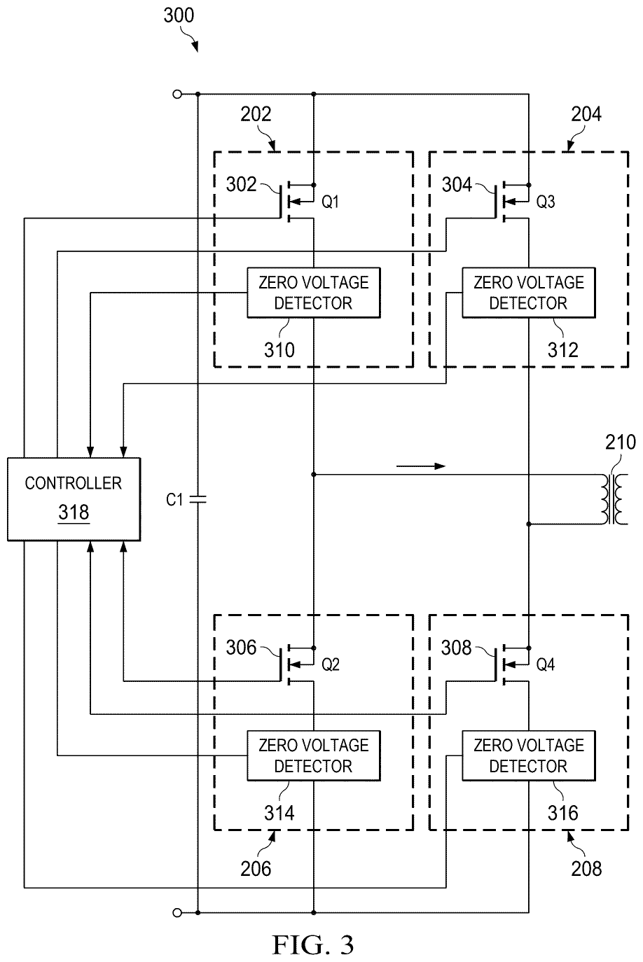

As described above, non-idealities and/or mismatch between the transistor circuitries 202, 204, 206, 208 can cause undesirable DC content in the AC current through the transformer 210. The DC content can cause the current to increase in the positive direction or the negative direction until the transformer 210 becomes saturated and the current will exponentially increase, thereby damaging the transistor circuitries 202, 204, 206, 208 and/or other components of the system 200. An undesirable level of DC content can also make soft switching more difficult. Thus, the system 200 includes the DC blocking capacitors 212, 214 to block the DC content adjusting the AC current through the transformer 210. However, as described above, the DC capacitors 212, 214 need to be sufficiently large and have very low equivalent series resistance (ESR) (e.g., to reduce power loss) to properly mitigate DC content in high switching environments. Thus, the use of capacitors 212, 214 adds significant PCB area and cost to transformer topologies. Also, even with low ESR, a capacitor-based technique results in some power loss. Additionally, the current sensors 216, 218 can sense the AC current so that a controller can identify DC content based on the sensed current to mitigate the DC content. However, as described above, like the capacitor approach, the use of the current sensors 216, 218 also results in a significant increase in PCB area, cost, and/or power loss. Accordingly, zero volt detection circuitry can be leveraged to mitigate DC content in the AC current through the transformer 210 without extra space, cost, and/or power loss, as further described below in conjunction with FIG. 3.

This disclosure describes techniques for DC content balancing that can be implemented without the DC capacitors 212, 214 and the current sensors 216, 218. Nonetheless, the techniques of this disclosure can be implemented in system having one or more DC capacitors and/or one or more current sensors. Thus, the techniques of this disclosure can be implemented in addition to or as an alternative to other approaches that use the DC capacitors 212, 214 and/or the current sensors 216, 218 to achieve DC content balancing.

FIG. 3 illustrates example circuitry 300 to implement a portion of the system of FIG. 2 without the need for capacitors or current sensors to detect and/or mitigate DC content. The circuitry 300 of FIG. 3 includes the transistor circuitries 202, 204, 206, 208 and the transformer 210 of FIG. 2. The circuitry 300 further includes transistors 302, 304, 306, 308, zero voltage detection circuitry 310, 312, 314, 316, and an example controller 318. Although the example of FIG. 3 illustrates a full bridge structure for the transistor circuitries 202, 204, 206, 208, examples disclosed herein can be described in conjunction with a half bridge structure (e.g., including two transistors, for example).

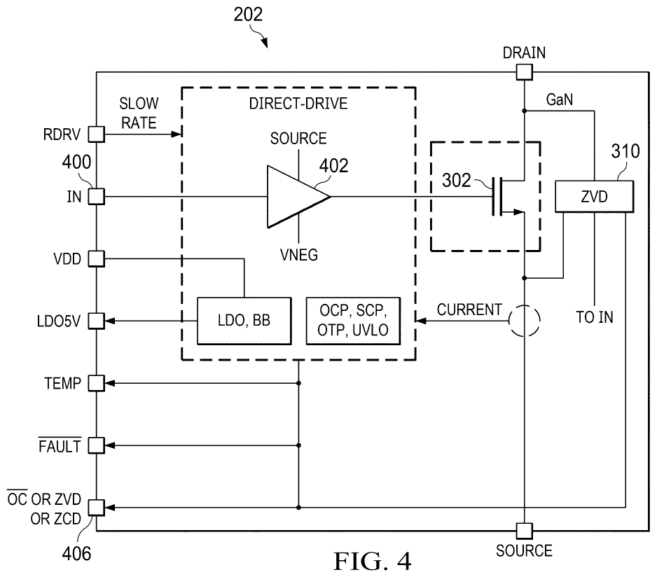

Each of the transistor circuitries 202, 204, 206, 208 of FIG. 3 include a transistor and a zero voltage detection circuit. For example, the transistor circuitry 202 includes the transistor 302 and the zero voltage detection circuitry 310, the transistor circuitry 204 includes the transistor 304 and the zero voltage detection circuitry 312, the transistor circuitry 206 includes the transistor 306 and the zero voltage detection circuitry 314, and the transistor circuitry 208 includes the transistor 308 and the zero voltage detection circuitry 316. Additionally, the one or more of the transistor circuitries 202, 204, 206, 208 may include other circuitries, such as a gate driver, as further described below in conjunction with FIG. 4. The transistors 302, 304, 306, 308 may be Gallium nitride (GaN) transistors, metal oxide semiconductor field effect transistors (MOSFETS), Silicon carbide (SiC) transistors, and/or another type of transistor or switch. The use of GaN and/or SiC transistors allows for the controller 318 to efficiently implement faster switching frequencies. The transistors 302, 304, 306, 308 are n-channel transistors that operate as switches based on a voltage applied to the gate of the respective transistors 302, 304, 306, 308. For example, if the voltage at the gate of the transistor 302 is a high voltage, the transistor 302 conducts, thereby operating as a closed switch. If the voltage at the gate of the transistor is a low voltage, the transistor 302 does not conduct, thereby operating as an open switch.

The transistor 302 of FIG. 3 includes a first current terminal (e.g., a drain terminal) coupled to the positive supply voltage (e.g., the positive terminal of the power source 201 of FIG. 2). The transistor 302 further includes a second current terminal (e.g., a source terminal) coupled to a first current terminal of the transistor 306 and a first terminal of the transformer 210. The transistor 302 further includes a control terminal (e.g., a gate terminal) coupled to the controller 318. In some examples, the control terminal of the transistor 302 is coupled to the controller 318 via a gate driver. The transistor 304 includes a first current terminal (e.g., a drain terminal) coupled to the positive supply voltage (e.g., the positive terminal of the power source 201 of FIG. 2). The transistor 304 further includes a second current terminal (e.g., a source terminal) coupled to a first current terminal of the transistor 308 and a second terminal of the transformer 210. The transistor 304 further includes a control terminal (e.g., a gate terminal) coupled to the controller 318. In some examples, the control terminal of the transistor 304 is coupled to the controller 318 via a gate driver. The transistor 306 includes a first current terminal (e.g., a drain terminal) coupled to the second current terminal of the transistor 302 and a second terminal of the transformer 210. The transistor 306 further includes a second current terminal (e.g., a source terminal) coupled to a negative voltage supply terminal or a common/ground terminal (e.g., the negative terminal of the power source 201 of FIG. 2). The transistor 306 further includes a control terminal (e.g., a gate terminal) coupled to the controller 318. In some examples, the control terminal of the transistor 306 is coupled to the controller 318 via a gate driver. The transistor 308 includes a first current terminal (e.g., a drain terminal) coupled to the second current terminal of the transistor 304 and the second terminal of the transformer 210. The transistor 308 further includes a second current terminal (e.g., a source terminal) coupled to a negative voltage supply terminal or a common/ground terminal (e.g., the negative terminal of the power source 201 of FIG. 2). The transistor 308 further includes a control terminal (e.g., a gate terminal) coupled to the controller 318. In some examples, the control terminal of the transistor 308 is coupled to the controller 318 via a gate driver.

The zero voltage detection circuitries 310, 312, 314, 316 of FIG. 3 are circuits that may already be implemented within the chip that implements the transistor circuitries 202, 204, 206, 208. In some examples, the zero voltage detection circuitries 310, 312, 314, 316 may be circuits implemented outside of the transistor circuitries 202, 204, 206, 208. The zero voltage detection circuitries 310, 312, 314, 316 output a pulse when the corresponding transistor has achieved zero voltage switching during a current switching cycle. For example, the zero voltage detection circuitry 310 will output a pulse when the voltage at the control terminal of the GaN transistor 302 goes high (e.g., causing the GaN transistor 302 to conduct to operate as a closed circuit) and the drain-to-source voltage (Vds) of the GaN transistor 302 is negative. When DC content is not an issue, the Vds being below zero when the control terminal of the GaN transistor 302 goes high indicates that the Vds has reached zero within the last period of the PWM signal used to control the GaN transistor 302. As further described below, a pulse from the zero voltage detection circuitries 310, 312, 314, 316 corresponds to a soft switching event of the corresponding transistor circuitries 202, 204, 206, 208 and no pulse from the zero voltage detection circuitries 310, 312, 314, 316 corresponds to a hard switching event of the corresponding transistor circuitries 202, 204, 206, 208. A hard switching event is when a transistor turns on or off (e.g., to operate as a closed circuit or an open circuit) while both voltage and current are present. A soft switching event is when a transistor turns on or off while the voltage or current is near zero. Because the zero voltage detection circuitries 310, 312, 314, 316 monitor Vds of the respective transistors 302, 304, 306, 308 when the input signal transitions, each of the zero voltage detection circuitries 310, 312, 314, 316 is coupled to the control terminal, the first current terminal, and/or the second current terminal of the respective transistors 302, 304, 306, 308, as further described below in conjunction with FIG. 4. Additionally, the zero voltage detection circuitries 310, 312, 314, 416 are coupled to the controller 318.

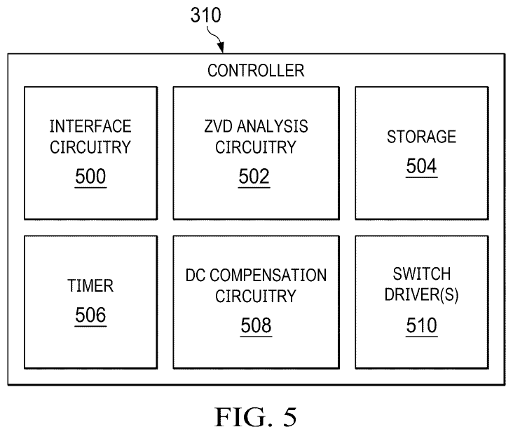

The controller 318 of FIG. 3 outputs control signals (e.g., PWM signals) to the gates of the transistors 302, 304, 306, 308 to control the transistors 302, 304, 306, 308. As further described above, the controller 318 may output a first PWM signal to the transistor 302 and a second PWM signal opposite the first PWM signal to the transistor 306. Additionally, the controller 318 can output a third PWM signal to the transistor 304 that is phase shifted from the first PWM signal and a fourth PWM signal opposite the third PWM signal to the transistor 308. The PWM signals correspond to duty cycles and/or dead times. The duty cycle corresponds to the percentage of a period that the PWM signal is high vs low and the dead time corresponds to an amount of time when the first and second PWM signals and/or the third and fourth PWM signals are both low. The controller 318 receives the zero voltage detection signals from the zero voltage detection circuitries 310, 312, 314, 316. The controller 318 can determine (a) a hard switch event or a soft switch event for the transistors 302, 304, 306, 308 and (b) whether the Vds voltage of the transistor 302, 304, 306, 308 is negative when the corresponding transistor 302, 304, 306, 308 is turned on based on the signal from the zero voltage detection circuitries 310, 312, 314, 316. When there is no DC current in the AC signal through the transformer 210, the signals from the ZVD signals will pulse for every period of the AC signal. Thus, the controller 318 can determine if there is DC content in the AC signal based on the presence or lack of pulses in one or more of the ZVD signals output by the ZVD circuitries 310, 312, 314, 316, as further described below in conjunction with FIG. 5. The controller 318 can adjust control of the transistors 302, 304, 306, 308 based on the ZVD signals from the ZVD circuitries 310, 312, 314, 316 based on the ZVD signals corresponding to DC content in the AC signal (e.g., based on a lack of pulse(s) in one or more of the ZVD signals). The controller 318 adjusts control of the transistors 302, 304, 306, 308 to mitigate the DC content. The controller 318 can adjust control of the transistors 302, 304, 306, 308 to mitigate the DC content by adjusting the duty cycle (e.g., the on-time), adjusting the dead time, etc. The controller 318 can dynamically adjust control of the transistors 302, 304, 306, 308 by more aggressively adjusting the control signals based on a number of missing pulses, an amount of time since the last pulse was received, etc. The controller 318 is further described below in conjunction with FIG. 5.

FIG. 4 illustrates an example implementation of the transistor circuitry 202 of FIGS. 2 and 3. However, FIG. 4 may be used to describe any of the transistor circuitries 202, 204, 206, 208 of FIGS. 2 and 3. The transistor circuitry 202 of FIG. 4 includes the example transistor 302 and the example ZVD circuitry 310 of FIG. 3. The transistor circuitry 202 of FIG. 4 further includes an example input terminal 400, an example gate driver 402, and an example ZVD terminal 406.

The input terminal 400 of FIG. 4 is coupled to the controller 318 of FIG. 3 and receives a control signal (e.g., a PWM signal) that is applied to the control terminal of the transistor 302 via the gate driver 402. The gate driver 402 receives the input signal from the controller 318 and amplifies the signal to a voltage/current high enough to properly control (e.g., turn on and off) the transistor 302 by controlling the voltage applied to the control terminal of the transistor 302. The gate driver 402 includes an input terminal that is coupled to the ZVD circuitry 310 and the controller 318 via the input terminal 400. The gate driver 402 further includes an output terminal coupled to the control terminal of the transistor 302.

In the example transistor circuitry 202 of FIG. 4, the ZVD circuitry 310 is coupled to the first current terminal, the second current terminal of the transistor 302, the input terminal 400, and the ZVD terminal 406. As described above, the ZVD circuitry 310 determines the Vds of the transistor 302 when the input 400 adjusts from a low voltage to a high voltage (e.g., to turn on the transistor 302 to conduct and operate as a closed switch). If ZVD circuitry 310 determines that the Vds of the transistor 302 is negative after the input 400 adjusts from a low voltage to a high voltage, the ZVD circuitry 310 outputs a pulse to the controller 318 via the ZVD terminal 406. Otherwise, the ZVD circuitry 310 does not output a pulse.

FIG. 5 is a block diagram of an example implementation of the controller 318 of FIG. 3. The controller 318 of FIG. 5 includes interface circuitry 500, example ZVD analysis circuitry 502, example storage 504, an example timer 506, example DC compensation circuitry 508, and example switch driver(s) 510. Although the example of FIG. 5 is described in conjunction with the full bridge structure of FIG. 3, FIG. 5 may be used to control other structures (e.g., a half bridge structure).

The interface circuitry 500 of FIG. 5 receives ZVD signal(s) from the one or more ZVD circuitries 310, 312, 314, 316. As described above, the ZVD signal(s) include a pulse per period of the AC current through the transformer 210 when the voltage at the control terminal of the corresponding transistor transitions from a low voltage to a high voltage and the Vds of the corresponding transistor is negative (e.g., corresponding to a soft switch event). If the Vds of the transistor is positive when the control terminal transitions from a low voltage to a high voltage, the ZVD signal does not include pulse of the period.

The ZVD analysis circuitry 502 of FIG. 5 determines whether there is DC content in the AC signal through the transformer 210 based on one or more of the ZVD signals (e.g., based on ZVD signal pulse(s), soft vs hard switching events, etc.) from the ZVD circuitries 310, 312, 314, 316. The ZVD analysis circuitry 502 can analyze the ZVD signals to identify DC content in various different ways. For example, the ZVD analysis circuitry 502 can identify DC content by analyzing a number of pulses from a single ZVD signal or by comparing a number of pulses from two or more ZVD signals. For example, the ZVD analysis circuitry 502 can determine that positive DC content is in the AC current based on a pulse not being included within a period of a ZVD signal from the ZVD circuitry 310 or the ZVD circuitry 316. Also, the ZVD analysis circuitry 502 can determine that negative DC content is in the AC current based on a pulse not being included within a period of a ZVD signal from the ZVD circuitry 312 or the ZVD circuitry 314. In some examples, the ZVD analysis circuitry 502 may discard one or more periods without a pulse to account for noise. The number of periods to discard may be based on user and/or manufacturer preferences. In some examples, the ZVD analysis circuitry 502 can determine that positive or negative DC content in the AC signal by comparing the number of pulses in the ZVD signal from the ZVD circuitry 310 to the number of pulses in the ZVD signal from the ZVD circuitry 314 (or the number of pulses in the ZVD signal from the ZVD circuitry 312 to the number of pulses in the ZVD signal from the ZVD circuitry 316) within a duration of time.

In some examples, the ZVD analysis circuitry 502 of FIG. 5 determines that DC content is in the AC signal based on a mismatch between the number of ZVD pulses from high side transistor circuitry (e.g., the transistor circuitry 202) to the number of ZVD pulses from low side transistor circuitry (e.g., the transistor circuitry 206). If the number of ZVD pulses from the high side transistor circuitry is higher than the number of pulses from the low side transistor circuitry, the ZVD analysis circuitry 502 determines that there is negative DC content in the AC signal. If the number of ZVD pulses from the high side transistor circuitry is lower than the number of pulses from the low side transistor circuitry, the ZVD analysis circuitry 502 determines that there is positive DC content in the AC signal. If the number of ZVD pulses from the high side transistor circuitry is the same as the number of pulses from the low side transistor circuitry, the ZVD analysis circuitry 502 determines that there is no DC content in the AC signal. In some examples, the ZVD analysis circuitry 502 determines that DC content is in the AC signal based on whether a difference between the number of high side ZVD pulses and the number of low side ZVD pulses being above or below a threshold, where the threshold can be user and/or manufacturer selected to avoid inaccurate ZVD signal due to noise. For example, if the threshold is set to one, the ZVD analysis circuitry 502 can subtract the number low size ZVD pulses for five periods from the number of high side ZVD pulses for five periods. If the difference is greater than one or less than negative one, the ZVD analysis circuitry 502 determines that DC content is in the AC signal (e.g., negative DC content if the difference is above 1 and positive DC content if the difference is below −1). For such comparisons, the ZVD analysis circuitry 502 can apply a static window (e.g., compare the pulse counts after every time duration corresponding to X periods) or a moving window (e.g., compare the pulse counts from the last X periods for each period).

The storage 504 of FIG. 5 stores the pulse counts for one or more of the ZVD circuitries 310, 312, 314, 316. For static windows, the storage 504 stores the count of pulses for a preset amount of time (e.g., corresponding to X periods of the AC signal) and resets the count after the ZVD analysis circuitry 502 makes a comparison. For dynamic windows, the storage 504 stores a count of pulses for one or more of the ZVD circuitries 310, 312, 314, 316 based on the last X periods of the AC signal.

The timer 506 of FIG. 5 tracks a duration of time so that the ZVD analysis circuitry 502 can determine when to compare pulses corresponding to one or more periods of the AC signal. For example, if the period of the AC signal is 100 microseconds and the ZVD analysis circuitry 502 is making comparisons based on 5 periods, the ZVD analysis circuitry 502 will compare the number of pulses after 500 microseconds based on the time tracked by the timer 506.

The DC compensation circuitry 508 of FIG. 5 performs one or more DC compensation techniques based on the ZVD analysis circuitry 502 identifying DC content in the AC signal. For example, if the ZVD analysis circuitry 502 determines that there is positive DC content in the AC signal, the DC compensation circuitry 508 can perform one or more DC compensation techniques to lower the AC signal. Likewise, if the ZVD analysis circuitry 502 determines that there is negative DC content in the AC signal, the DC compensation circuitry 508 can perform one or more DC compensation techniques to increase the AC signal. The DC compensation techniques may include one or more of adjusting the duty cycle of the control signals applied to the control terminals of the transistors 302, 304, 306, 308, adjusting the dead time of the control signals applied to the control terminals of the transistors 302, 304, 306, 308, etc. In some examples, the DC compensation circuitry 508 can perform dynamic DC compensation techniques based on the ZVD analysis. For example, the DC compensation circuitry 508 can further adjust or more aggressively adjust the duty cycle, dead time, etc. of a control signal based on a large number of missing pulses from one or more ZVD signals, one or more missing pulses missing after a previous DC compensation technique was already applied, etc.

The switch driver(s) 510 of FIG. 5 output control signals to the control terminals of the transistors 302, 304, 306, 308. For example, the switch driver(s) 510 outputs PWM signals to each of the transistors 302, 304, 306, 308 to cause the transistors 302, 304, 306, 308 to conduct or not conduct to cause current to flow through the transformer 210 of FIG. 2. As described above, the PWM signal can be phase shifted so that the control signal to transistor 302 is the opposite of the control signal to the transistor 306 and the control signal to the transistor 304 is opposite of the control signal to the transistor 308 and the control signal to the transistor 302 is phase shifted from the control signal to the transistor 308.

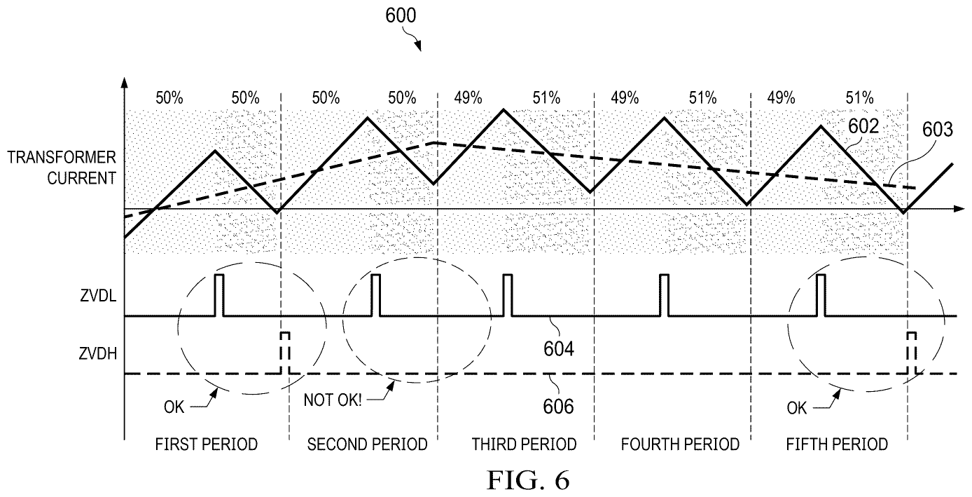

FIG. 6 is an example timing diagram 600 that illustrates an example transformer current plot 602, an example DC content plot 603, an example low side ZVD plot (ZVDL) 604, and an example high side ZVD plot (ZVDH) 606. Although FIG. 6 includes an example timing diagram 600, the timing diagram 600 may correspond to a different transformer current leading to a different DC content plot, ZVDL plot, and ZVDH plot.

The transformer current plot 602 of FIG. 6 corresponds to an AC current (e.g., a triangle wave) that flows through the transformer 210 of FIGS. 2 and 3. The transformer current plot 602 increases and decreases based on which transistors 302, 304, 306, 308 are conducting. The current plot 602 is broken up into 5 periods, where each of the 5 periods may correspond to a switching cycle in the system 200. The DC content plot 603 corresponds to the DC content in the transformer current plot 602. As shown, as the DC content plot 603 increases, the current plot 602 increases. Thus, instead of having a negative current at the end of the low side control (e.g., when one or more of the transistors 306, 304 are conducting) and a positive current at the end of high side control (e.g., when one or more of the transistors 302, 308 are conducting), by the second period, the transformer current plot 602 is always positive throughout the period due to the DC content in the transformer current.

The ZVDL plot 604 corresponds to the signal output by the ZVD circuitry 314 and the ZVDH plot 606 corresponds to the signal output by the ZVD circuitry 310. During the first period, when the low side transistor 306 adjusts from not conducting to conducting, the low side ZVD circuitry 314 determines that the Vds of the transistor 306 is negative (e.g., the transformer current flows from the first terminal of the transformer 210 to the second terminal of the transformer 210). Thus, during the first period, the ZVDL plot 604 pulses. Also, during the first period, when the transistor 302 adjusts from not conducting to conducting, the ZVD circuitry 310 determines that the Vds of the transistor 306 is negative (e.g., the transformer current flows from the second terminal of the transformer 210 to the first terminal of the transformer 210). Thus, during the first period, the ZVDH plot 604 pulses.

During the second period, the DC content plot 603 causes the transformer current plot 602 to increase. Accordingly, during the second period, when the low side transistor 306 adjusts from not conducting to conducting, the low side ZVD circuitry 314 determines that the Vds of the transistor 306 is negative (e.g., the transformer current flows from the first terminal of the transformer 210 to the second terminal of the transformer 210). Thus, during the second period, the ZVDL plot 604 pulses. Also, during the second period, when the transistor 302 adjusts from not conducting to conducting, the ZVD circuitry 310 determines that the Vds of the transistor 306 is not negative (e.g., the transformer current flows from the first terminal of the transformer 210 to the second terminal of the transformer 210). Thus, during the second period, the ZVDH plot 604 does not pulse. Accordingly, the controller 318 can determine that positive DC content is in the transformer content and adjusts the duty cycle of the PWM control signal of the transistors 302, 304, 306, 308. Accordingly, from the third period to the fifth period, the controller 318 adjusts the duty cycle to 49/51 so that within a period, the high side control is enabled for 49% of the period and the low side control is enabled for 51% of the period, thereby causing the transformer current to decrease over time and mitigating the DC content. Additionally or alternatively, the controller 318 could perform an additional or alternative DC content mitigation technique(s), for example using different duty cycle values for the transistors. Although the controller 318 has applied a DC content mitigation technique, the transformer current 602 does not decrease to below 0 until the fifth period. In some examples, the controller 318 may dynamically adjust the duty cycle (e.g., to 48/52) for the fifth period because the ZVDH signal does not pulse after the fourth period. After the fifth period, the controller 318 may return the duty cycle to the initial duty cycle (e.g., 50/50) or may continue with the adjusted duty cycle until the ZVDL signal 604 does not pulse within the time for an entire switching cycle.

To trigger an adjustment, the controller 318 may be configurable to detect that a pulse on the ZVDL signal 604 is missing during the second period shown in FIG. 6. In response to determining that a pulse on the ZVDL signal 604 is missing during the second period, the controller 318 can determine that undesirable DC content is present in the transformer current. Additionally or alternatively, the controller 318 can trigger an adjustment based on other determinations. For example, the controller 318 may be configurable to trigger an adjustment in response to detecting a mismatch in pulses on the ZVDL and ZVDH signals 604 and 606 during the second period. The controller 318 can detect the mismatch by determining that a pulse was received in the ZVDL signal 604 but no pulse was received in the ZVDH signal 606 during the second period.

As another example, the controller 318 may be configurable to trigger an adjustment in response to detecting the number of pulses on the ZVDH signal 606 over a particular time duration was below a threshold value. The controller 318 can maintain a counter of the number of pulses on the ZVDH signal 606 over one or more periods can compare this number to a threshold value that is equal to or less than the number of periods (e.g., the number of periods minus one, to prevent triggering the adjustment for a single missed pulse). Thus, the controller 318 can trigger an adjustment by determining that the number of pulses on the ZVDL or ZVDH signal 604, 606 is less than the number of periods (e.g., switching cycles).

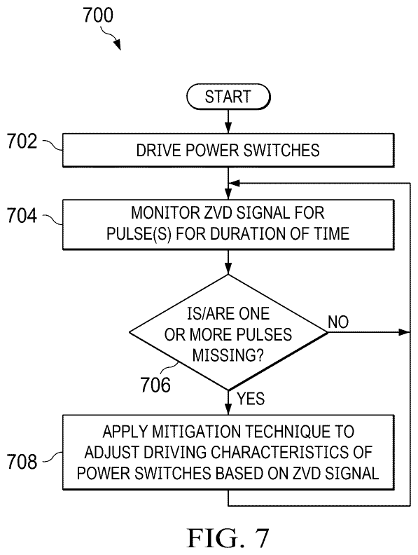

FIG. 7 is a flowchart representative of a method and/or example operations 700 that may be executed and/or instantiated by the controller 318 of FIGS. 3 and/or 5. The operations 700 can be performed by any one or combination of the circuitry shown in FIGS. 2-3. Although the instructions and/or operations of FIG. 7 are described in conjunction with the system 200 and/or circuitry 300 of FIGS. 2 and 3, the instructions and/or operations may be described in conjunction with any type of circuit that implements processing circuitry. Some processes shown in FIG. 7 may be performed in orders other than described, and many processes may be performed concurrently in parallel. Furthermore, processes shown in FIG. 7 may be omitted or substituted in some examples of the present description. Although the example of FIG. 7 is described in conjunction with the full bridge structure of FIG. 3, FIG. 7 may be used to control other structures (e.g., a half bridge structure).

The machine-readable instructions and/or the operations 700 of FIG. 7 begin at block 702, at which the switch driver(s) 510 drive the power transistors 302, 304, 306, 308 using PWM signals, as further described above in conjunction with FIG. 5. At block 704, the ZVD analysis circuitry 502 monitors a ZVD signal (e.g., from one of the ZVD circuitries 310, 312, 314, 316). As described above, a ZVD signal will not pulse when there is DC content in the AC signal through the transformer 210. Accordingly, at block 706, the ZVD analysis circuitry 502 determines if one or more pulses are missing from the ZVD signal, thereby corresponding to a hard switching event and/or DC content being in the AC current. In some examples, the ZVD analysis circuitry 502 may determine whether a single pulse is missing for one period. In some examples, the ZVD analysis circuitry 502 may determine whether a threshold number of pulses are missing during multiple periods (e.g., to discard one or more periods that may correspond to false negatives due to noise).

If the ZVD analysis circuitry 502 determines that one or more pulses are not missing from the monitored ZVD signal (block 706: NO), control returns to block 704 and the ZVD analysis circuitry 502 continues to monitor the ZVD signal(s) for pulses. If the ZVD analysis circuitry 502 determines that one or more pulses are missing from the monitored ZVD signal (block 706: YES), the DC compensation circuitry 508 applies a mitigation technique to adjust the driving characteristics of the power transistors 302, 304, 306, 308 based on the monitored ZVD signal (block 708). For example, if the ZVD analysis circuitry 502 determines that one or more pulses are missing from the ZVD circuitry 310, 316 that corresponds to the transistors 302, 308, then the DC compensation circuitry 508 determines that there is positive DC content in the AC signal. Accordingly, the DC compensation circuitry 508 may adjust the PWM signals applied to the transistors 302, 304, 306, 308 so that the transistors 304, 306 are conducting for longer than the transistors 302, 308 for each period, thereby reducing the DC content in the AC signal. If the ZVD analysis circuitry 502 determines that one or more pulses are missing from the ZVD circuitry 312, 314 that corresponds to the transistors 304, 306, then the DC compensation circuitry 508 determines that there is negative DC content in the AC signal. Accordingly, the DC compensation circuitry 508 may adjust the PWM signals applied to the transistors 302, 304, 306, 308 so that the transistors 304, 306 are conducting for shorter than the transistors 302, 308 for each period, thereby increasing the DC content in the AC signal. Additionally or alternatively, the DC compensation circuitry 508 may perform other compensation techniques, such as increasing the deadtime of the PWM signal(s) applied to the transistor 302, 304, 306, 308. In some examples, the DC compensation circuitry 508 may perform dynamic DC content compensation techniques, as further described above.

In some examples, if pulses are missing from both the ZVDL and ZVDH signals or the same number of pulses are missing from both the ZVDL and ZVDH signals, the DC compensation circuitry 508 may not apply a mitigation technique. For example, there may be some situations where a hard switching event occurs for both high side transistors and low side transistors and a DC mitigation technique is not needed.

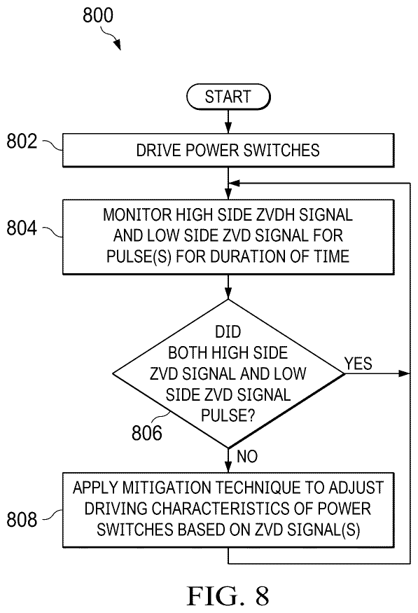

FIG. 8 is a flowchart representative of a method and/or example operations 800 that may be executed and/or instantiated by the controller 318 of FIGS. 3 and/or 5. The operations 800 can be performed by any one or combination of the circuitry shown in FIGS. 2-3. Although the instructions and/or operations of FIG. 8 are described in conjunction with the system 200 and/or circuitry 300 of FIGS. 2 and 3, the instructions and/or operations may be described in conjunction with any type of circuit that implements processing circuitry. Some processes shown in FIG. 8 may be performed in orders other than described, and many processes may be performed concurrently in parallel. Furthermore, processes shown in FIG. 8 may be omitted or substituted in some examples of the present description. Although the example of FIG. 8 is described in conjunction with the full bridge structure of FIG. 3, FIG. 8 may be used to control other structures (e.g., a half bridge structure).

The machine-readable instructions and/or the operations 800 of FIG. 8 begin at block 802, at which the switch driver(s) 510 drive(s) the power transistors 302, 304, 306, 308 using PWM signals, as further described above in conjunction with FIG. 5. At block 804, the ZVD analysis circuitry 502 monitors a high side ZVD signal (e.g., from one or more of the ZVD circuitries 310, 316) and a low side ZVD signal (e.g., from one or more of the ZVD circuitries 312, 314) for pulse(s) for a duration of time. The duration of time may be tracked by the timer 506 and may correspond to one period of the PWM signals. As described above, a ZVD signal will not pulse when there is DC content in the AC signal through the transformer 210. Accordingly, at block 806, the ZVD analysis circuitry 502 determines if both the high side ZVD signal and the low side ZVD signal pulsed within the period. If both the high side ZVD signal and the low side ZVD signal both pulse, the ZVD analysis circuitry 502 determines that soft switching event occurred on both the transistors 302, 308 and the transistors 304, 306 and that there is no or minimal DC content in the AC signal through the transformer 210. If one of the high side ZVD signal or the low side ZVD signal does not pulse, then the ZVD analysis circuitry 502 determines that there was a hard switch event for the corresponding transistors and there is DC content in the AC signal.

If the ZVD analysis circuitry 502 determines that both the high side ZVD signal and the low side ZVD signal pulse (block 806: YES), control returns to block 804 and the ZVD analysis circuitry 502 continues to monitor the ZVD signal(s) for pulses. If the ZVD analysis circuitry 502 determines that one of the high side ZVD signal or the low side ZVD signal does not pulse (block 806: NO), the DC compensation circuitry 508 applies a mitigation technique to adjust the driving characteristics of the power transistors 302, 304, 306, 308 based on the monitored ZVD signals (block 808). For example, if the ZVD analysis circuitry 502 determines that one or more pulses are missing from the ZVD circuitry 310, 316 that corresponds to the transistors 302, 308, then the DC compensation circuitry 508 determines that there is positive DC content in the AC signal. Accordingly, the DC compensation circuitry 508 may adjust the PWM signals applied to the transistors 302, 304, 306, 308 so that the transistors 304, 306 are conducting for longer than the transistors 302, 308 for each period, thereby reducing the DC content in the AC signal. If the ZVD analysis circuitry 502 determines that one or more pulses are missing from the ZVD circuitry 312, 314 that corresponds to the transistors 304, 306, then the DC compensation circuitry 508 determines that there is negative DC content in the AC signal. Accordingly, the DC compensation circuitry 508 may adjust the PWM signals applied to the transistors 302, 304, 306, 308 so that the transistors 304, 306 are conducting for shorter than the transistors 302, 308 for each period, thereby increasing the DC content in the AC signal. Additionally or alternatively, the DC compensation circuitry 508 may perform other compensation techniques, such as increasing the deadtime of the PWM signal(s) applied to the transistor 302, 304, 306, 308. In some examples, the DC compensation circuitry 508 may perform dynamic DC content compensation techniques, as further described above.

In some examples, if pulses are missing from both the ZVDL and ZVDH signals or the same number of pulses are missing from both the ZVDL and ZVDH signals, the DC compensation circuitry 508 may not apply a mitigation technique. For example, there may be some situations where a hard switching event occurs for both high side transistors and low side transistors and a DC mitigation technique is not needed.

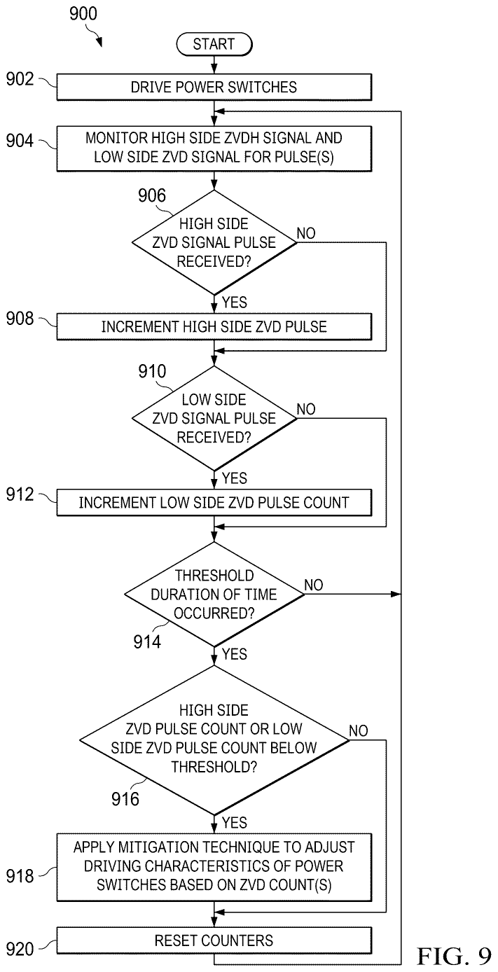

FIG. 9 is a flowchart representative of a method and/or example operations 900 that may be executed and/or instantiated by the controller 318 of FIGS. 3 and/or 5. The operations 900 can be performed by any one or combination of the circuitry shown in FIGS. 2-3. Although the instructions and/or operations of FIG. 9 are described in conjunction with the system 200 and/or circuitry 300 of FIGS. 2 and 3, the instructions and/or operations may be described in conjunction with any type of circuit that implements processing circuitry. Some processes shown in FIG. 9 may be performed in orders other than described, and many processes may be performed concurrently in parallel. Furthermore, processes shown in FIG. 9 may be omitted or substituted in some examples of the present description. Although the example of FIG. 9 is described in conjunction with the full bridge structure of FIG. 3, FIG. 9 may be used to control other structures (e.g., a half bridge structure).

The machine-readable instructions and/or the operations 900 of FIG. 9 begin at block 902, at which the switch driver(s) 510 drive the power transistors 302, 304, 306, 308 using PWM signals, as further described above in conjunction with FIG. 5. At block 904, the ZVD analysis circuitry 502 monitors one or more high side ZVD signals (e.g., from one or more of the ZVD circuitries 310, 316) and one or more low side ZVD signals (e.g., from one or more of the ZVD circuitries 312, 314) for pulse(s) for a duration of time. As described above, a ZVD signal will not pulse when there is DC content in the AC signal through the transformer 210. At block 906, the ZVD analysis circuitry 502 determines whether a pulse in the high side ZVD signal (e.g., from one or more of the ZVD circuitries 310, 316) has been received. If a high side ZVD signal pulse has not been received (block 906: NO), control continues to block 910. If a high side ZVD signal pulse has been received (block 906: YES), the ZVD analysis circuitry 502 increases a high side ZVD pulse count stored in the storage 504 (block 908). At block 910, the ZVD analysis circuitry 502 determines whether a pulse in the low side ZVD signal (e.g., from one or more of the ZVD circuitries 312, 314) has been received. If a low side ZVD signal pulse has not been received (block 910: NO), control continues to block 914. If a low side ZVD signal pulse has been received (block 910: YES), the ZVD analysis circuitry 502 increases a low side ZVD pulse count stored in the storage 504 (block 912).

At block 914, the timer 506 determines if a duration of time has occurred. The duration of time may correspond to one or more periods of the PWM signals based on user and/or manufacturer preferences. If the timer 506 determines that the threshold duration of time has not occurred (block 914: NO), control returns to block 904 to continue monitoring ZVD signals. If the timer 506 determines that the threshold duration of time has occurred (block 914: YES), the ZVD analysis circuitry 502 determines if the high side ZVD pulse count or the low side ZVD pulse count is below a threshold (block 916). The threshold may be based on the number of periods that the timer 506 tracks. For example, if a comparison of counts occurs after every five periods, the threshold may be four. In this manner, the ZVD analysis circuitry 502 can determine if the high side ZVD pulse count and the low side ZVD pulse count is four or above for the five periods. Alternatively, the ZVD analysis circuitry 502 may compare the high side ZVD pulse count to the low side ZVD pulse count. For example, the ZVD analysis circuitry 502 can determine a difference between the high side ZVD pulse count and the low side ZVD pulse count and trigger a mitigation technique is the difference is above a first threshold (e.g., one) or below a second threshold (e.g., negative one).

If the ZVD analysis circuitry 502 determines that the high side ZVD pulse count and low side ZVD pulse count are not below the threshold (e.g., corresponding to low or no DC content and/or a soft switching event) (block 916: NO), control continues to block 920. If the ZVD analysis circuitry 502 determines that the high side ZVD pulse count or low side ZVD pulse count is below the threshold (e.g., corresponding to DC content and/or a hard switching event) (block 916: NO), the DC compensation circuitry 508 applies a mitigation technique to adjust the driving characteristics of the power transistors 302, 304, 306, 308 based on the monitored ZVD signals (block 918). For example, if the ZVD analysis circuitry 502 determines that the high side ZVD pulse count is below a threshold, then the DC compensation circuitry 508 determines that there is positive DC content in the AC signal. Accordingly, the DC compensation circuitry 508 may adjust the PWM signals applied to the transistors 302, 304, 306, 308 so that the transistors 304, 306 are conducting for longer than the transistors 302, 308 for each period, thereby reducing the DC content in the AC signal. If the ZVD analysis circuitry 502 determines that the low side ZVD pulse count is below a threshold, then the DC compensation circuitry 508 determines that there is negative DC content in the AC signal. Accordingly, the DC compensation circuitry 508 may adjust the PWM signals applied to the transistors 302, 304, 306, 308 so that the transistors 304, 306 are conducting for shorter than the transistors 302, 308 for each period, thereby increasing the DC content in the AC signal. Additionally or alternatively, the DC compensation circuitry 508 may perform other compensation techniques, such as increasing the deadtime of the PWM signal(s) applied to the transistor 302, 304, 306, 308. In some examples, the DC compensation circuitry 508 may perform dynamic DC content compensation techniques, as further described above.

In some examples, if the ZVDL and ZVDH pulse counts are both below the threshold, the DC compensation circuitry 508 may not apply a mitigation technique. For example, there may be some situations where a hard switching event occurs for both high side transistors and low side transistors and a DC mitigation technique is not needed. At block 920, the ZVD analysis circuitry 502 resets the counters and control returns to block 904.

Although the flowchart of FIG. 9 is described in conjunction with comparing pulse counts within a first duration of time followed by comparison pulse counts within a second subsequent duration of time, FIG. 9 may be adjusted to describe a moving window of comparison. For example, instead of comparing the pulse counts to the threshold after X periods, the ZVD analysis circuitry 502 can compare the pulse counts after each period, where the counts correspond to pulse from the last Y periods.

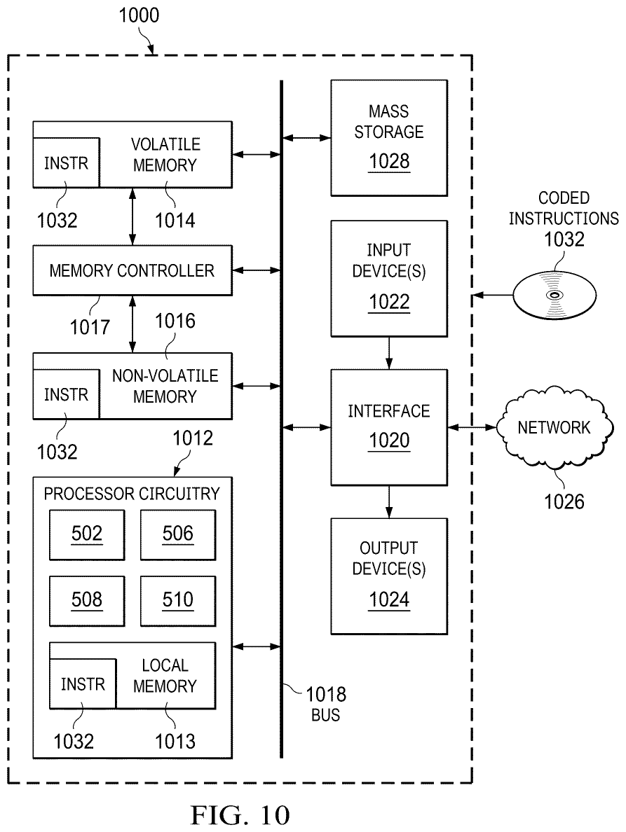

FIG. 10 is a block diagram of an example programmable circuitry platform 1000 structured to execute and/or instantiate the example machine-readable instructions and/or the example operations of FIGS. 7-9 to implement the controller 318 of FIG. 5. The programmable circuitry platform 1000 can be, for example, a server, a personal computer, a microcontroller, logic, an FPGA, or any other type of computing and/or electronic device.

The programmable circuitry platform 1000 of the illustrated example includes programmable circuitry 1012. The programmable circuitry 1012 of the illustrated example is hardware. For example, the programmable circuitry 1012 can be implemented by one or more integrated circuits, logic circuits, FPGAs, microprocessors, CPUs, GPUs, VPUs, DSPs, and/or microcontrollers from any desired family or manufacturer. The programmable circuitry 1012 may be implemented by one or more semiconductor based (e.g., silicon based) devices. In this example, the programmable circuitry 1012 implements the ZVD analysis circuitry 502, the timer 506, the DC compensation circuitry 508, and the switch driver(s) 510.

The programmable circuitry 1012 of the illustrated example includes a local memory 1013 (e.g., a cache, registers, etc.). The programmable circuitry 1012 of the illustrated example is in communication with main memory 1014, 1016, which includes a volatile memory 1014 and a non-volatile memory 1016, by a bus 1018. The volatile memory 1014 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1016 may be implemented by flash memory and/or any other desired type of memory device. Access to the main memory 1014, 1016 of the illustrated example is controlled by a memory controller 1017. In some examples, the memory controller 1017 may be implemented by one or more integrated circuits, logic circuits, microcontrollers from any desired family or manufacturer, or any other type of circuitry to manage the flow of data going to and from the main memory 1014, 1016. Any one or more of the main memory 1014, 1016 or local memory 1013 can implement the storage 504 of FIG. 5

The programmable circuitry platform 1000 of the illustrated example also includes interface circuitry 1020. The interface circuitry 1020 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface. The interface circuitry 1020 may implement the interface circuitry 500 of FIG. 5.

In the illustrated example, one or more input devices 1022 are connected to the interface circuitry 1020. The input device(s) 1022 permit(s) a user (e.g., a human user, a machine user, etc.) to enter data and/or commands into the programmable circuitry 1012. The input device(s) 1022 can be implemented by, for example, an audio sensor, a microphone, a camera (still or video), a keyboard, a button, a mouse, a touchscreen, and/or a voice recognition system.

One or more output devices 1024 are also connected to the interface circuitry 1020 of the illustrated example. The output device(s) 1024 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, and/or speaker. The interface circuitry 1020 of the illustrated example, thus, typically includes a graphics driver card, a graphics driver chip, and/or graphics processor circuitry such as a GPU.

The interface circuitry 1020 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1026. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1000 of the illustrated example also includes one or more mass storage discs or devices 1028 to store firmware, software, and/or data. Examples of such mass storage discs or devices 1028 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 1032, which may be implemented by the machine readable instructions of FIGS. 7-9, may be stored in the mass storage device 1028, in the volatile memory 1014, in the non-volatile memory 1016, and/or on at least one non-transitory computer readable storage medium such as a CD or DVD which may be removable.

An example manner of implementing the controller 318 of FIG. 3 is illustrated in FIG. 5. However, one or more of the elements, processes and/or devices illustrated in FIG. 5 may be combined, divided, re-arranged, omitted, eliminated, and/or implemented in any other way.

Further, the interface circuitry 500, the ZVD analysis circuitry 502, the storage 504, the timer 506, the DC compensation circuitry 508, and/or the switch driver(s) 510 of FIG. 5 may be implemented by hardware, software, firmware and/or any combination of hardware, software and/or firmware. As a result, for example, any the interface circuitry 500, the ZVD analysis circuitry 502, the storage 504, the timer 506, the DC compensation circuitry 508, and/or the switch driver(s) 510 of FIG. 5 could be implemented by one or more analog or digital circuit(s), logic circuits, programmable processor(s), programmable controller(s), graphics processing unit(s) (GPU(s)), digital signal processor(s) (DSP(s)), application specific integrated circuit(s) (ASIC(s)), programmable logic device(s) (PLD(s)) and/or field programmable logic device(s) (FPLD(s)).

When reading any of the apparatus or system claims of this patent to cover a purely software and/or firmware implementation, at least one of the interface circuitry 500, the ZVD analysis circuitry 502, the storage 504, the timer 506, the DC compensation circuitry 508, and/or the switch driver(s) 510 of FIG. 5 is/are hereby expressly defined to include a non-transitory computer readable storage device or storage disk such as a memory, a digital versatile disk (DVD), a compact disk (CD), a Blu-ray disk, etc., including the software and/or firmware. Further still, the interface circuitry 500, the ZVD analysis circuitry 502, the storage 504, the timer 506, the DC compensation circuitry 508, and/or the switch driver(s) 510 of FIG. 5 may include one or more elements, processes and/or devices in addition to, or instead of, those illustrated in FIG. 5, and/or may include more than one of any or all of the illustrated elements, processes, and devices. As used herein, the phrase “in communication,” including variations thereof, encompasses direct communication and/or indirect communication through one or more intermediary components, and does not require direct physical (e.g., wired) communication and/or constant communication, but rather also includes selective communication at periodic intervals, scheduled intervals, aperiodic intervals, and/or one-time events.

Flowcharts representative of example hardware logic, machine-readable instructions, hardware implemented state machines, and/or any combination thereof for implementing the controller 318 of FIG. 5 are shown in FIGS. 7-9. The machine-readable instructions may be one or more executable programs or portion(s) of an executable program for execution by a computer processor. The program may be embodied in software stored on a non-transitory computer readable storage medium such as a CD-ROM, a floppy disk, a hard drive, a DVD, a Blu-ray disk, or a memory associated with the processor, but the entire program and/or parts thereof could alternatively be executed by a device other than the processor and/or embodied in firmware or dedicated hardware.

Further, although the example program is described with reference to the flowcharts illustrated in FIGS. 7-9, many other methods of implementing the controller 318 may alternatively be used. For example, the order of execution of the blocks may be changed, and/or some of the blocks described may be changed, eliminated, or combined. Also or alternatively, any or all of the blocks may be implemented by one or more hardware circuits (e.g., discrete and/or integrated analog and/or digital circuitry, a field-programmable gate array (FPGA), an application-specific integrated circuit (ASIC), a comparator, an operational-amplifier (op-amp), a logic circuit, etc.) structured to perform the corresponding operation without executing software or firmware.

The machine-readable instructions described herein may be stored in one or more of a compressed format, an encrypted format, a fragmented format, a compiled format, an executable format, a packaged format, etc. Machine-readable instructions as described herein may be stored as data (e.g., portions of instructions, code, representations of code, etc.) that may be utilized to create, manufacture, and/or produce machine executable instructions. For example, the machine-readable instructions may be fragmented and stored on one or more storage devices and/or computing devices (e.g., servers). The machine-readable instructions may require one or more of installation, modification, adaptation, updating, combining, supplementing, configuring, decryption, decompression, unpacking, distribution, reassignment, compilation, etc. in order to make them directly readable, interpretable, and/or executable by a computing device and/or other machine. For example, the machine-readable instructions may be stored in multiple parts, which are individually compressed, encrypted, and stored on separate computing devices, in which the parts when decrypted, decompressed, and combined form a set of executable instructions that implement a program such as that described herein.

In another example, the machine-readable instructions may be stored in a state in which they may be read by a computer, but require addition of a library (e.g., a dynamic link library (DLL)), a software development kit (SDK), an application programming interface (API), etc. in order to execute the instructions on a particular computing device or other device. In another example, the machine-readable instructions may be configured (e.g., settings stored, data input, network addresses recorded, etc.) before the machine-readable instructions and/or the corresponding program(s) can be executed in whole or in part. As a result, the described machine-readable instructions and/or corresponding program(s) encompass such machine-readable instructions and/or program(s) regardless of the particular format or state of the machine-readable instructions and/or program(s) when stored or otherwise at rest or in transit.

The machine-readable instructions described herein can be represented by any past, present, or future instruction language, scripting language, programming language, etc. For example, the machine-readable instructions may be represented using any of the following languages: C, C++, Java, C-sharp, Perl, Python, JavaScript, HyperText Markup Language (HTML), Structured Query Language (SQL), Swift, etc.

As mentioned above, the example processes of FIG. 3 may be implemented using executable instructions (e.g., computer and/or machine-readable instructions) stored on a non-transitory computer and/or machine-readable medium such as a hard disk drive, a flash memory, a read-only memory, a compact disk, a digital versatile disk, a cache, a random-access memory and/or any other storage device or storage disk in which information is stored for any duration (e.g., for extended time periods, permanently, for brief instances, for temporarily buffering, and/or for caching of the information). As used herein, the term non-transitory computer readable medium is expressly defined to include any type of computer readable storage device and/or storage disk and to exclude propagating signals and to exclude transmission media.

Although certain example methods, apparatus and articles of manufacture have been described herein, the scope of coverage of this patent is not limited thereto. On the contrary, this patent covers all methods, apparatus and articles of manufacture fairly falling within the scope of the claims of this patent.

Descriptors “first,” “second,” “third,” etc. are used herein when identifying multiple elements or components which may be referred to separately. Unless otherwise specified or known based on their context of use, such descriptors do not impute any meaning of priority, physical order, or arrangement in a list, or ordering in time but are merely used as labels for referring to multiple elements or components separately for ease of understanding the described examples. In some examples, the descriptor “first” may be used to refer to an element in the detailed description, while the same element may be referred to in a claim with a different descriptor such as “second” or “third.” In such instances, such descriptors are used merely for ease of referencing multiple elements or components.

In the description and in the claims, the terms “including” and “having” and variants thereof are to be inclusive in a manner similar to the term “comprising” unless otherwise noted. Unless otherwise stated, “about,” “approximately,” or “substantially” preceding a value means +/−10 percent of the stated value. In another example, “about,” “approximately,” or “substantially” preceding a value means +/−5 percent of the stated value. IN another example, “about,” “approximately,” or “substantially” preceding a value means +/−1 percent of the stated value.

The term “couple” “coupled”, “couples”, and variants thereof, as used herein, may cover connections, communications, or signal paths that enable a functional relationship consistent with this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A. Moreover, the terms “couple,” “coupled,” “couples,” or variants thereof, includes an indirect or direct electrical or mechanical connection.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

Although not all separately labeled in the FIGS. 1-2, components or elements of systems and circuits illustrated therein have one or more conductors or terminus that allow signals into and/or out of the components or elements. The conductors or terminus (or parts thereof) may be referred to herein as pins, pads, terminals (including input terminals, output terminals, reference terminals, and ground terminals, for instance), inputs, outputs, nodes, and interconnects.

As used herein, a “terminal” of a component, device, system, circuit, integrated circuit, or other electronic or semiconductor component, generally refers to a conductor such as a wire, trace, pin, pad, or other connector or interconnect that enables the component, device, system, etc., to electrically and/or mechanically connect to another component, device, system, etc. A terminal may be used, for instance, to receive or provide analog or digital electrical signals (or simply signals) or to electrically connect to a common or ground reference. Accordingly, an input terminal or input is used to receive a signal from another component, device, system, etc. An output terminal or output is used to provide a signal to another component, device, system, etc. Other terminals may be used to connect to a common, ground, or voltage reference, e.g., a reference terminal or ground terminal. A terminal of an IC or a PCB may also be referred to as a pin (a longitudinal conductor) or a pad (a planar conductor). A node refers to a point of connection or interconnection of two or more terminals. An example number of terminals and nodes may be shown. However, depending on a particular circuit or system topology, there may be more or fewer terminals and nodes. However, in some instances, “terminal,” “node,” “interconnect,” “pad,” and “pin” may be used interchangeably.

The terms “or” and “and/or” as used, for example, in a form such as A, B, or C or A, B, and/or C refers to any combination or subset of A, B, C such as (1) A alone, (2) B alone, (3) C alone, (4) A with B, (5) A with C, (6) B with C, or (7) A with B and with C.

Example methods, apparatus, systems, and articles of manufacture for direct current balancing using a zero voltage detection signal are described herein. Further examples and combinations thereof include the following: Example 1 includes a system comprising a transformer circuit, a transistor coupled to the transformer circuit, zero voltage detection circuitry coupled to the transistor, and a controller coupled to the transistor, coupled to the zero voltage detection circuitry, and configurable to receive a signal from the zero voltage detection circuitry, detect that one or more pulses are missing from the signal received from the zero voltage detection circuitry, and control the transistor in response to detecting that the one or more pulses are missing from the signal.

Example 2 includes the subject matter of any proceeding clause, wherein to control the transistor, the controller is configurable to adjust a duty cycle of a control signal output by the controller to the transistor.

Example 3 includes the subject matter of any proceeding clause, wherein to control the transistor, the controller is configurable to adjust a dead time of a control signal output by the controller to the transistor.

Example 4 includes the subject matter of any proceeding clause, wherein to detect that the one or more pulses are missing, the controller is configurable to determine that a number of the one or more pulses is less than a number of switching cycles.

Example 5 includes the subject matter of any proceeding clause, wherein to detect that the one or more pulses are missing, the controller is configurable to determine that no pulses were received by the controller in the signal from the zero voltage detection circuitry during one or more switching cycles.

Example 6 includes the subject matter of any proceeding clause, wherein to detect that the one or more pulses are missing, the controller is configurable to determine that a number of pulses in the signal received by the controller from the zero voltage detection circuitry is less than a threshold value.

Example 7 includes a system comprising a transformer circuit, a first transistor coupled to the transformer circuit, first zero voltage detection circuitry coupled to the first transistor, a second transistor coupled to the transformer circuit, second zero voltage detection circuitry coupled to the second transistor, and a controller coupled to the first transistor, the first zero voltage detection circuitry, the second transistor, and the second zero voltage detection circuitry, wherein the controller is operable to control the first transistor and the second transistor based on a mismatch between a first signal received from the first zero voltage detection circuitry and a second signal received from the second zero voltage detection circuitry.

Example 8 includes the subject matter of any proceeding clause, wherein the controller is to identify direct current content in an alternating current through the transformer circuit based on at least one of the first signal including a first number of pulses less than a threshold value or the second signal including a second number of pulses less than the threshold value.

Example 9 includes the subject matter of any proceeding clause, wherein the first zero voltage detection circuitry is operable to output a pulse during a soft switch event of the first transistor, and not output a pulse during a hard switch event of the first transistor.

Example 10 includes the subject matter of any proceeding clause, wherein the soft switch event corresponds to a drain-to-source voltage of the first transistor being negative when the first transistor turns on, and wherein the hard switch event corresponds to the drain-to-source voltage of the first transistor being positive when the first transistor turns on.

Example 11 includes the subject matter of any proceeding clause, wherein the first transistor includes a gallium nitride transistor.

Example 12 includes the subject matter of any proceeding clause, wherein the first transistor includes a driver circuit coupled to the controller, and wherein the gallium nitride transistor is coupled to the transformer circuit and the driver circuit.

Example 13 includes the subject matter of any proceeding clause, wherein the transformer circuit includes a first coil and a second coil, and wherein the first transistor and the second transistor are coupled to the first coil of the transformer circuit.

Example 14 includes the subject matter of any proceeding clause, further including a battery coupled to the first transistor and coupled to the second transistor, a third transistor coupled to the second coil of the transformer circuit and the battery, and a fourth transistor coupled to the second transistor, the second coil of the transformer circuit, and the battery.

Example 15 includes the subject matter of any proceeding clause, wherein each of the first transistor and the third transistor is structured to be coupled to a power supply.

Example 16 includes the subject matter of any proceeding clause, wherein the first transistor is a high side transistor, and wherein the second transistor is a low side transistor.

Example 17 includes the subject matter of any proceeding clause, wherein the controller is operable to control the first transistor and the second transistor by adjusting at least one of a duty cycle of control signals applied to the first transistor and the second transistor, or a dead time of the control signals applied to the first transistor and the second transistor.

Example 18 includes a system comprising a transformer, a first transistor coupled to the transformer, a second transistor coupled to the transformer, first zero voltage detection circuitry operable to output a pulse based on a drain to source voltage of the first transistor being negative when the first transistor turns on, second zero voltage detection circuitry operable to output a pulse based on a drain-to-source voltage of the second transistor being negative when the second transistor turns on, and a controller coupled to the first zero voltage detection circuitry and the second zero voltage detection circuitry, wherein the controller is operable to mitigate direct current content in an alternative current applied to the transformer based on at least one of a first count of pulses from the first zero voltage detection circuitry or a second count of pulses from the second zero voltage detection circuitry.

Example 19 includes the subject matter of any proceeding clause, wherein the controller is operable to output a first control signal to control the first transistor and a second control signal to control the second transistor.

Example 20 includes the subject matter of any proceeding clause, wherein the controller is operable to mitigate the direct current content by adjusting at least one of the first control signal or the second control signal.

Modifications are possible in the described embodiments, and other embodiments are possible, within the scope of the claims.

What is claimed is:

1. A system comprising:
a transformer circuit;
a transistor coupled to the transformer circuit;
zero voltage detection circuitry coupled to the transistor; and
a controller coupled to the transistor, coupled to the zero voltage detection circuitry, and configurable to:
receive a signal from the zero voltage detection circuitry;
detect that one or more pulses are missing from the signal received from the zero voltage detection circuitry; and
control the transistor in response to detecting that the one or more pulses are missing from the signal.

2. The system of claim 1, wherein to control the transistor, the controller is configurable to adjust a duty cycle of a control signal output by the controller to the transistor.

3. The system of claim 1, wherein to control the transistor, the controller is configurable to adjust a dead time of a control signal output by the controller to the transistor.

4. The system of claim 1, wherein to detect that the one or more pulses are missing, the controller is configurable to determine that a number of the one or more pulses is less than a number of switching cycles.

5. The system of claim 1, wherein to detect that the one or more pulses are missing, the controller is configurable to determine that no pulses were received by the controller in the signal from the zero voltage detection circuitry during one or more switching cycles.

6. The system of claim 1, wherein to detect that the one or more pulses are missing, the controller is configurable to determine that a number of pulses in the signal received by the controller from the zero voltage detection circuitry is less than a threshold value.

7. A system comprising:
a transformer circuit;
a first transistor coupled to the transformer circuit;
first zero voltage detection circuitry coupled to the first transistor;
a second transistor coupled to the transformer circuit;
second zero voltage detection circuitry coupled to the second transistor; and
a controller coupled to the first transistor, the first zero voltage detection circuitry, the second transistor, and the second zero voltage detection circuitry,
wherein the controller is operable to control the first transistor and the second transistor based on a mismatch between a first signal received from the first zero voltage detection circuitry and a second signal received from the second zero voltage detection circuitry.

8. The system of claim 7, wherein the controller is to identify direct current content in an alternating current through the transformer circuit based on at least one of the first signal including a first number of pulses less than a threshold value or the second signal including a second number of pulses less than the threshold value.

9. The system of claim 7, wherein the first zero voltage detection circuitry is operable to:
output a pulse during a soft switch event of the first transistor; and
not output a pulse during a hard switch event of the first transistor.

10. The system of claim 9,
wherein the soft switch event corresponds to a drain-to-source voltage of the first transistor being negative when the first transistor turns on, and
wherein the hard switch event corresponds to the drain-to-source voltage of the first transistor being positive when the first transistor turns on.

11. The system of claim 7, wherein the first transistor includes a gallium nitride transistor.

12. The system of claim 11,
wherein the first transistor includes a driver circuit coupled to the controller, and
wherein the gallium nitride transistor is coupled to the transformer circuit and the driver circuit.

13. The system of claim 7,
wherein the transformer circuit includes a first coil and a second coil, and
wherein the first transistor and the second transistor are coupled to the first coil of the transformer circuit.

14. The system of claim 13, further including:
a battery coupled to the first transistor and coupled to the second transistor;
a third transistor coupled to the second coil of the transformer circuit and the battery; and
a fourth transistor coupled to the second transistor, the second coil of the transformer circuit, and the battery.

15. The system of claim 14, wherein each of the first transistor and the third transistor is structured to be coupled to a power supply.

16. The system of claim 7,
wherein the first transistor is a high side transistor, and
wherein the second transistor is a low side transistor.

17. The system of claim 7, wherein the controller is operable to control the first transistor and the second transistor by adjusting at least one of:
a duty cycle of control signals applied to the first transistor and the second transistor; or
a dead time of the control signals applied to the first transistor and the second transistor.

18. A system comprising:
a transformer;
a first transistor coupled to the transformer;
a second transistor coupled to the transformer;
first zero voltage detection circuitry operable to output a pulse based on a drain to source voltage of the first transistor being negative when the first transistor turns on;
second zero voltage detection circuitry operable to output a pulse based on a drain-to-source voltage of the second transistor being negative when the second transistor turns on; and
a controller coupled to the first zero voltage detection circuitry and the second zero voltage detection circuitry, wherein the controller is operable to mitigate direct current content in an alternative current applied to the transformer based on at least one of a first count of pulses from the first zero voltage detection circuitry or a second count of pulses from the second zero voltage detection circuitry.

19. The system of claim 18, wherein the controller is operable to output a first control signal to control the first transistor and a second control signal to control the second transistor.

20. The system of claim 19, wherein the controller is operable to mitigate the direct current content by adjusting at least one of the first control signal or the second control signal.
